(19) United States
(12) Patent Application Publication
(10) Pub. No.: US 2024/0431054 A1
(43) Pub. Date: Dec. 26, 2024

(54) MODULAR ELECTRICAL INTERFACE

(71) Applicant: BELIMO HOLDING AG, Hinwil (CH)

(72) Inventors: Josef NIEDERBERGER, Dürnten (CH); Peter BÖHLE, Hombrechtikon (CH); Simon BLÖCHLINGER, Wagen (CH)

(21) Appl. No.: 18/708,187

(22) PCT Filed: Oct. 28, 2022
(86) PCT No.: PCT/EP2022/080230

§ 371 Date: May 7, 2024

(30) Foreign Application Priority Data
Nov. 16, 2021 (CH) CH070565/2021
Mar. 18, 2022 (CH) CH000290/2022

(51) Int. Cl. H05K 5/02; F24F 11/88; H05K 5/00

(52) U.S. Cl. CPC H05K 5/0247; F24F 11/88; H05K 5/0069

(57) ABSTRACT

A device for use in an HVAC application may have a housing including a housing body consisting of walls that determine an inner space of the housing. Connecting frames establish an edge of receiving slots for receiving standard solder-free connectors. At the outer face of the connecting frames connecting lugs are formed. Furthermore, the device has an electrical interface module. The electrical interface module includes a standard solder-free connector and a tension protection module. The standard solder-free connector may be connected directly to a printed circuit board and fixed by the tension protection module.

### TECHNICAL FIELD

The application relates to HVAC systems, in particular devices for measuring and regulating the flow of fluid in such systems. Furthermore, the application relates to a method of mounting a device for use in an HVAC application.

### BACKGROUND

In the field of heating, ventilation and air-conditioning systems (HVAC) of buildings, in particular residential buildings, office buildings, commercial buildings and industrial buildings, automatic fluid flow measurement and regulation becomes more and more important. To this end, the buildings are equipped with a plurality of sensors and actuators for measuring and regulating, respectively, the flow of fluid. These field devices implement one or more electrical and/or mechanical functions and/or other functions (e.g. hydraulic, optical) and comprise—but not limited to—actuators, sensors, or a combination thereof. They are usually combined in one compact unit and accommodated in a housing.

Furthermore, each of these devices is controlled or powered via a printed circuit board (PCB). The PCB is connected to a communication bus and to a power supply by lead wires which are conventionally connected to the PCB by soldering. Typically, a cable is connected to the housing which provides and/or receives electrical signals to or from the HVAC actuator or sensor for controlling these devices, and also provides electric current for powering these components.

However, the use of solder connections is not preferred because it complicates assembly and under certain conditions solder connections may break or be insufficient.

Furthermore, in conventional devices the cable connection may be destroyed easily by application of external forces.

### SUMMARY

It is an object of the present disclosure to provide a device for use in an HVAC application having a stable electrical interface for supplying electric power and/or control signals to the PCB of the device.

This object is attained by providing a device for use in an HVAC application and a method for mounting the same.

A device for use in an HVAC application according to the present disclosure comprises:
a housing having walls determining an inner space, wherein the housing has at least one slot for receiving a connector, and a mounting section;
a printed circuit board (PCB) arranged in said housing for controlling and operating the device, wherein the PCB comprises connecting terminals; and
a modular electrical interface, comprising:
   at least one connector having lead wires, wherein the connector is received in said slot of said housing, wherein the lead wires have a solder-free connection to corresponding connecting terminals of the PCB; and
   a tension protection module fixed to said mounting section of said housing.

The device may be a modular system comprising a field device for detecting and/or controlling a fluid flow in an HVAC application, e. g. in a building. The device may comprise an actuator and/or a sensor.

The present disclosure provides a modular system comprising a connector (e. g. PCB direct plug) and a tension protection module. Due to the modular approach there is high design flexibility, since the tension protection module can be selected from different components. Various combinations and configurations can be created, as the connection to the housing and the positioning of the tension protection module relative to the connector is the same for all different tension protection modules. The present disclosure allows providing a terminal solution as well as a cable solution. The connection between the lead wires of the connector and the PCB is solder-free. Thus the disadvantages of solder connections can be avoided. Environmental and safety protection is ensured by including the tension protection module which absorbs all mechanical loads and stress applied to the cable.

A solder-free connection has various advantages. Solder-free connections allows implementing different patterns of connections. Thus there is high flexibility in applications using different patterns of connections, i.e. the same housing and connectors may be used for different applications. It is not necessary to implement additional PCB, i.e. the same PCB may be used for different applications. Furthermore, the cable can be fixed to the connector in any place, without having to use special tools, either be pre-mounted in a serial production site or directly at a building site where the field device (sensor, actuator, etc.) is installed.

In fact, the inventive solution provides a plug and play on site device for variable applications.

In a preferred embodiment of the present disclosure the connector may be a direct PCB connector. The connector may have a slot for receiving the terminal portion of the PCB for contacting with the contacts of lead wires provided in the connector. Electric power and/or control signals may be supplied to the PCB in order to power and control operation of the device.

It is preferred that the tension protection module is removably fixed to the mounting section.

The tension protection module may be fixed to the mounting section by means of a latching connection. Alternative fixations like form fit or positive fit or positive locking are explicitly not excluded.

Another inventive device for use in an HVAC application according to the present disclosure comprises:
a housing having walls determining an inner space, wherein the housing has at least one slot for receiving a connector, and a mounting section; and
a modular electrical interface, comprising:
at least one connector having lead wires, wherein the connector is received in said slot of said housing, wherein the lead wires have a solder-free connection to corresponding connecting terminals; and
a tension protection module fixed to said mounting section of said housing by a fixation, wherein the fixation includes at least a first connecting element which is a latch connector or a snap connector, and a second connecting element which is a positive fit connector.

In the context of the present disclosure a positive fit connection is any connection that is not simply releasable without a tool, including e.g. screw fittings, bolted connections, a combination of a lug and a bolt, etc. A positive fit connector corresponds to a first type of connectors which may be released only by using a tool.

On the other hand, a snap or latch connection in the context of the present disclosure is any connection which can be released without using a tool, particularly any connections that comprise at least a moveable portion that may be actuated in order to disengage release the connection. A snap connector or latch connector corresponds to a second type of connectors which may be released without using a tool.

The first type of connectors and the second type of connectors are commonly used for connecting a particular tension protection module to a particular housing. According to this aspect of the present disclosure, the first type of connectors and the second type of connectors are different types.

Particularly, the device comprises a printed circuit board (PCB) arranged in the housing for controlling and operating the device, wherein the PCB comprises connecting terminals.

In a preferred embodiment of the present disclosure the connector is a direct PCB connector.

Particularly, the lead wires have a solder-free connection to corresponding connecting terminals of the PCB.

The mounting section of the housing may comprise a frame part, and the tension protection module is fixed to the frame part. The frame part may have attachment means for fixing the tension protection module thereto. This fixation is strong enough to fulfil the requirements of applications in the relevant field.

The tension protection module may comprise at least one socket portion fixed to the mounting section of the housing. The socket portion may have an inner space which can receive the frame portion when the tension protection module is mounted to the housing. Furthermore, the tension protection module may comprise a latching element, e. g. a flexible bracket, which interacts with a corresponding latching element of the frame portion, e. g. a lug, to establish a latching connection formed at an exterior wall of the frame portion. The frame portion usually defines the edge of the opening of the slot for receiving the connector.

Furthermore, the tension protection module may comprise two or more socket portions fixed to corresponding mounting sections of the housing. The number and arrangement of socket portions of one tension protection module may correspond to the number and arrangement of slots for insertion of connectors.

If two or more connectors are used in one application, i. e. if two or more slots are provided, a mechanical coding system may be implemented. For example, a code of recesses and protrusions may be formed in the PCB and in the PVB direct plug connector. The recesses and protrusions block each other when the match is incorrect, and correspond to each other when the match is correct. Therefore, incorrect wiring can be avoided, e. g. low and high voltage power supply cannot be confused. The respective tension protection module may be shaped in a Y-form.

In another embodiment of the present disclosure the tension protection module may comprise a window or opening for exposing a portion of the connector, particularly the wire insertion portion of the connector. In this embodiment tension applied to the cable is transferred to the connector. However, the tension protection module still blocks the connector from being pushed out of the slot. For example, the tension protection module may comprise a socket wall enclosing the frame element of the housing, and a wall portion extending from the rear side of the socket wall inwardly to form a retainer for the connector received in the slot.

In another embodiment of the present disclosure the tension protection module comprises a connection part having an opening for receiving at least one cable, and a fixing element for fixing the at least one cable in a position relative to the tension protection module. The fixing element may be a screw fitting or a nut that can be tightened or released to block the cable or release it, respectively. When the cable is blocked, the end of the wires connected to the connector are fixed relative to the tension protection module and the connector. Therefore, forces applied to the cable are transferred to the housing via the tension protection module.

The connector may comprise an isolation housing having connection elements for connecting with corresponding connection elements formed in the slot of the housing for fixing the connector in the corresponding slot of said housing. The connector may have an attachment member, e. g. a latching or locking element, formed in a side wall of the connector insulating housing, in order to fix the connector in the slot, e. g. by means of a latching connection. The connector may have protrusions and/or depressions for co-operating with complementary attachment members formed in the slot. When the connector is inserted in the corresponding slot of the housing a fixation may be facilitated. However, this fixation is of low quality, i. e. it is not suitable for securing the connector reliably in the slot during operation of the device.

The first connecting element and the second connecting element may be arranged at different side walls of the connector housing, particularly on opposite sides and/or at opposite walls of a connecting frame of the housing.

The latch connector or snap connector may be provided for engaging with a corresponding third connecting element of the mounting section, and the positive fit connector is provided for engaging with a corresponding fourth connecting element of the mounting section.

The third connecting element may comprise a recess for engagement with the latch connector or snap connector.

In an embodiment of the present disclosure the latch connector or snap connector comprises a pivotable lever which is actuatable for disengagement of the latch connector or snap connector from the third connecting element. The lever comprises a protrusion at one end thereof for engaging the recess formed by the third connecting element. The lever may be pivoted by a user in order to disengage the snap/latch protrusion from the recess.

The positive fit connector may comprise a lug having an opening for a positive fit engagement with the fourth connecting element.

The fourth connecting element may comprise a protrusion which engages the opening of the lug.

The opening of the lug may be defined by an edge comprising a bracket portion which may be actuated using a tool for disengagement of the lug from the protrusion. The tool may be a screwdriver that bends the bracket away from the protrusion of the fourth connecting element so that the positive fit between the lug and the protrusion of the fourth connecting element is abandoned. Then the lug can be moved away from the protrusion of the fourth connecting element and the tension protection module can be removed from the housing.

The first and third connecting elements, and the lond and fourth connecting elements, respectively, may be interchanged, i.e. various snap/latch connections and positive fit connections are possible and claimed in this application.

At least one of the connecting terminals of the PCB may have a first layer comprising gold (Au) and a second layer comprising tin (Sn) deposited on said first layer.

The first layer may comprise a chemical Ni/Au layer.

The second layer may be provided as a solder paste.

A method according to the present disclosure of mounting a device as mentioned above comprises the steps:
a. Pre-mounting said connector, said tension protection module and said cable to obtain said modular electrical interface and the cable connected thereto;
b. Inserting at least a part of the connector in the slot of the housing and fixing the modular electrical interface to the housing.

There are various options for mounting the device and for securing the connector to the housing.

First, there is a cable solution. In the cable solution the PVB direct plug connector is fixed to the tension protection module. The PVB direct plug connector, the tension protection module and the wire (cable) can be pre-assembled or pre-mounted in advance. At the building site the pre-assembled module can be fixed to the housing, wherein the connection to the PCB is solder-free and direct.

Second, there is a terminal solution. In the terminal solution the PVB direct plug connector is fixed to the housing first, in order to establish a solder-free connection to the PCB. Then a suitable tension protection module is selected and fixed to the housing. It could be mounted on site as well.

In another embodiment of the present disclosure the tension protection module comprises an attachment section for attaching a conduit. In some high demanding applications a conduit has to be use for housing the cable and wires, respectively. The conduit may be attached to the attachment section of the tension protection module e.g. by a screw connection. If a tension protection module for two or more connectors is used which brings together the cables and wires in one connecting part, it is sufficient to use just one conduit for various connections.

Another device for use in an HVAC application according to the present disclosure comprises:
a housing having walls determining an inner space, wherein the housing has at least one slot for receiving a connector, and a mounting section;
a printed circuit board (PCB) arranged in the housing for controlling and operating the device, wherein the PCB comprises connecting terminals;
wherein at least one of the connecting terminals of the PCB has a first layer comprising gold (Au) and a second layer comprising tin (Sn) deposited on said first layer.

In a preferred embodiment of the present disclosure the device may comprise a modular electrical interface, comprising: at least one connector for supplying power and/or carry signals to the PCB, the connector having contacts, wherein the connector is received in said slot (12) of said housing, wherein the contacts are in a solder-free connection with the corresponding contact terminals of the PCB, when the connector is connected to the PCB.

In a preferred embodiment of the present disclosure the device may comprise a tension protection module fixed to said mounting section of said housing.

The present disclosure relates to PCB preparation for connectors having tin-plated contacts, particularly plug connectors. In the state of the art, when soldering fine pitch components, chemically treated surfaces (with gold (ENIG), silver or tin) were applied to the printed circuit boards, which enable qualitatively good soldering results for fine pitch components due to the possibility of manufacturing flat surfaces. Simpler and cheaper treatment methods for different materials, such as “Hot Air Solder Levelling (HASL), did not prove to reach comparable quality.

Furthermore, chemical tin and silver surfaces can only be soldered reliably within 6 months, compared to chemical gold (ENIG) which can be soldered within 12 months. Therefore, in applications that need high soldering quality electroless gold (ENIG) is used as the standard PCB surface finish and contact layer. Consequently, in order to avoid battery effects with oxidation/reduction effects caused by the contact of gold connection terminals of the PCB and tin contacts of the direct connector, direct connectors also had gold-plated contacts.

However, the present disclosure presents a new concept, namely (i) to provide connection/contact terminals on the PCB of the device which have a PCB surface with gold (ENIG), and (ii) to apply a tin coating to the gold (ENIG) coating in a reflow soldering process with solder paste. The resulting PCB contacts can be used in combination with tin-plated contacts of connector.

In another preferred embodiment of the present disclosure the connector has at least one contact which is tin (Sn) plated.

The PCB comprises a substrate made of an insulating base material like FR4, and conductive contacts, e.g. copper (Cu) contacts. ENIG material is coated on top of the copper contacts as a surface finish in order to increase the shelf life (durability, lifetime) of the PCB. On top of the ENIG layer solder paste comprising tin is deposited in order to ensure good surface properties and thus good contact with tin-plated contacts of connectors/plugs.

The first layer may be a chemical Ni/Au layer.

It is preferred that the second layer is provided as a solder paste. I.e. the reflow soldering process is used for manufacturing a contact layer comprising tin on top of the Ni/Au layer.

An inventive method of manufacturing a device according to the present disclosure comprises the steps:
a. Providing a PCB having at least one contact;
b. Depositing a first layer comprising gold (Au) on at least one of the contact;
c. Depositing a second layer on the first layer, wherein the second layer comprises tin (Sn).

Method step a) may include using an immersion gold process, particularly Electroless Nickel Immersion Gold (ENIG), for depositing the first layer, in order to form a uniform gold layer on the surface of the PCB.

Electroless nickel immersion gold (ENIG or ENi/IAu), also known as immersion gold (Au), chemical Ni/Au or soft gold, is a metal plating process used in the manufacture of printed circuit boards (PCBs) to avoid oxidation and improve the solderability of copper contacts. The layer includes an electroless nickel plating, covered with a thin layer of gold, which protects the nickel and the underlying copper contact from oxidation. The gold is typically applied by quick immersion in a solution containing gold salts. Some of the nickel is oxidized to Ni2+ while the gold is reduced to metallic state.

ENIG layers have high surface planarity, good oxidation resistance, and are suitable for plug-in connectors. If the ENIG layer is tin-plated by using solder paste, tin-plated connectors may be used.

Step b) may comprise applying solder paste comprising tin (Sn) on the first layer.

Usually, solder paste is used in manufacturing printed circuit boards (PCBs) to connect surface mount components to contact terminals/contact pads of the PCB. Solder paste is sticky and therefore temporarily holds components in place. Afterwards, the PCB is heated, the solder paste melts and forms a mechanical bond as well as an electrical connection between the contact and the pins. Solder paste may be applied to the PCB by processes including jet printing, stencil printing or via a syringe. Afterwards, the components are put in place e.g. by a pick-and-place machine.

In the present disclosure solder paste is not necessarily used for fixing surface mount components, but to manufacture the second layer of the contact terminals of the PCB.

Of course, manufacturing the second layer and fixing surface mount components could be combined in one reflow process.

Generally, solder is powdered solder suspended in flux paste. Solder paste according to the present disclosure comprises at least a portion of tin (Sn).

The method may comprise a further step d) of reflow soldering applied to the second layer deposited on the first layer.

An advantage of this embodiment is that the solder paste can be applied on the ENIG layer at the same time or separately from assembling electrical components in reflow soldering or in similar processes. Since the inventive PCB requires a reflow process anyway, this process could, at the same time, be used for fixing electrical components. I.e. the same solder paste and the same reflow process may be used for component placement (if it is required) and for manufacturing the second layer of the contact terminals of the PCB.

### BRIEF DESCRIPTION OF THE DRAWINGS

The present disclosure will be explained in greater detail with reference to the exemplary embodiments which are illustrated in the drawings.

FIG. 1 is a perspective view of the components of an embodiment of a device for use in an HVAC application according to the present disclosure in an unmounted state;

FIG. 2 is a view of components of another embodiment of a device for use in an HVAC application;

FIG. 3 is a top view, a perspective view and a back view of a component of another embodiment of a device for use in an HVAC application;

FIG. 4 is a top view of a component of another embodiment of a device for use in an HVAC application;

FIG. 5 is a perspective view of components of another embodiment of a device for use in an HVAC application;

FIG. 6 is a perspective view of components of still another embodiment of a device for use in an HVAC application;

FIG. 7 is a perspective view of a component of still another embodiment of a device for use in an HVAC application;

FIG. 8 is an illustration of a conduit for a cable.

FIG. 9 is a perspective view of a component of another embodiment of a device for use in an HVAC application;

FIG. 10 illustrates the use of blind plugs according to the present disclosure;

FIG. 11 is a perspective view of components of another embodiment of a device for use in an HVAC application;

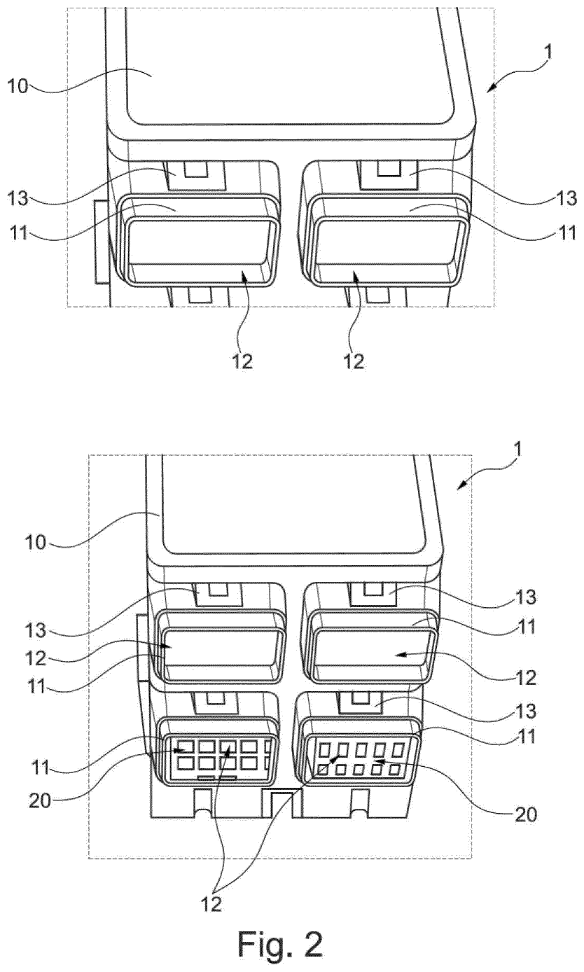

FIG. 2 12-14 illustrate different embodiments of Y-shaped tension protection modules;

FIGS. 15, 16 are perspective views of PCT direct plug solder-free connectors; and

FIGS. 17, 18 are perspective views of an alternative embodiment of an electrical interface module;

FIG. 19 is a perspective view from above of another embodiment of a device according to the present disclosure;

FIG. 20 is a perspective view from below of the embodiment of FIG. 19;

FIG. 21 is a perspective view of components of the embodiment of FIG. 19;

FIG. 22 is a side view of the components of the embodiment of FIG. 21;

FIG. 23 is a perspective view showing actuation of connecting elements of an inventive tension protection module;

FIG. 24 an embodiment of a PCB and a connector according to the present disclosure; and

FIG. 25 a sectional view of a portion the PCB of FIG. 24.

### DETAILED DESCRIPTION

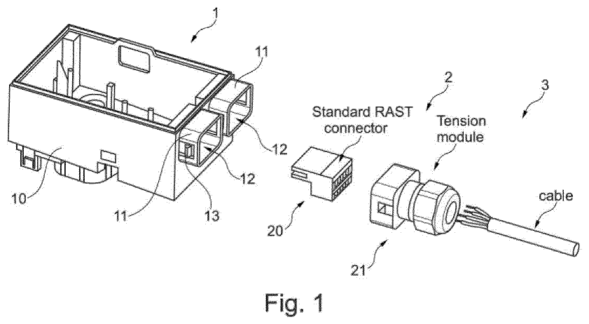

FIG. 1 illustrates components 1, 2, 3 of an embodiment of a device for use in an HVAC application according to the present disclosure in a unmounted state.

The first component is housing 1. The housing 1 includes a housing body 10 consisting of walls that determine an inner space of the housing 1, connecting frames 11 which establish an edge of receiving spaces 12/slots 12 for receiving standard solder-free connectors 20 (PVB direct plug). At the outer face of the connecting frames 11 connecting lugs 13 are formed (in FIG. 1 just one exemplary connecting lug 13 is indicated). Within the inner space of the housing 1 further components may be accommodated, namely, a printed circuit board (PCB) for controlling and powering other components, e. g. an actuator, a sensor, a gear, etc. (not illustrated).

Furthermore, the device comprises an electrical interface module 2. The electrical interface module 2 comprises a standard solder-free connector 20 and a tension protection module 21. The standard solder-free connector 20 may be connected directly to a printed circuit board, e. g. by a clamping connection, such that lead wires comprised in the connector 20 contact terminals formed on the top and/or on the bottom of the printed circuit board. The tension protection module 21 prevents the standard solder-free connector 20 or the ends of the cables 3 connected to the standard solder-free connector 20 to be stressed and removed from the housing 1.

Furthermore, the device includes a cable 3 which provides electric current for powering and operating the components within the housing 1 via the PCB, and for providing and receiving to and from, respectively, the PCB signals for controlling the operation of the device.

FIG. 2 illustrates embodiments of a housing 1. The housings 1 comprise two (2, picture on the left side) and four (4, picture on the right side) slots 12, each of them being suitable for receiving a standard solder-free connector 20 as shown in the bottom slots 12 in the picture on the right side. As can be seen in FIG. 2 the connecting frames 11 have connecting lugs 13 for connecting, fixing and securing a tension protection module (not illustrated).

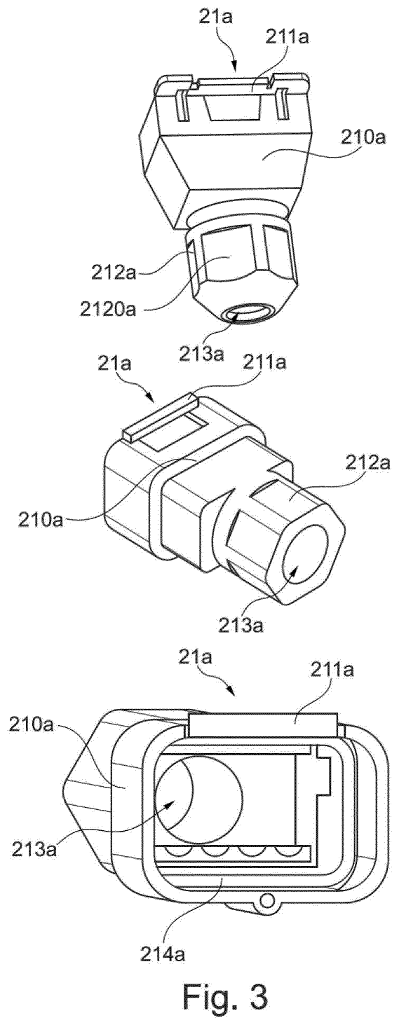

FIG. 3 shows a first embodiment of a tension protection module 21 a in three different perspectives. The tension protection module 21 a comprises a socket portion 210a which is suitable for receiving a connecting frame 11 when the module 21 a is attached to the housing 1. For removably fixing the module 21a to the housing, a connecting bracket 211a is formed at the socket portion 210a for establishing a latching connection with a corresponding connecting lug formed at the frame part of the housing (not illustrated). On the opposite side (back side) the socket portion 210a has a connecting piece for connecting a screw fitting or nut fitting 212a.

The module 21a has a fixing screw fitting 212a (cable gland, cable clamping) mounted to the connecting piece of the socket portion 210a. The screw fitting 212a and the connecting piece have an opening 213a for receiving a cable or several cables that are to be fixed to a connector 20 as described above, e. g. by crimping. When the screw fitting 212a is tightened, a cable or several cables may be squeezed and thus be fixed in position relative to the connector 20. In this way, uncontrolled movement or removal of the cable 3 from the tension protection module 21 may be prevented.

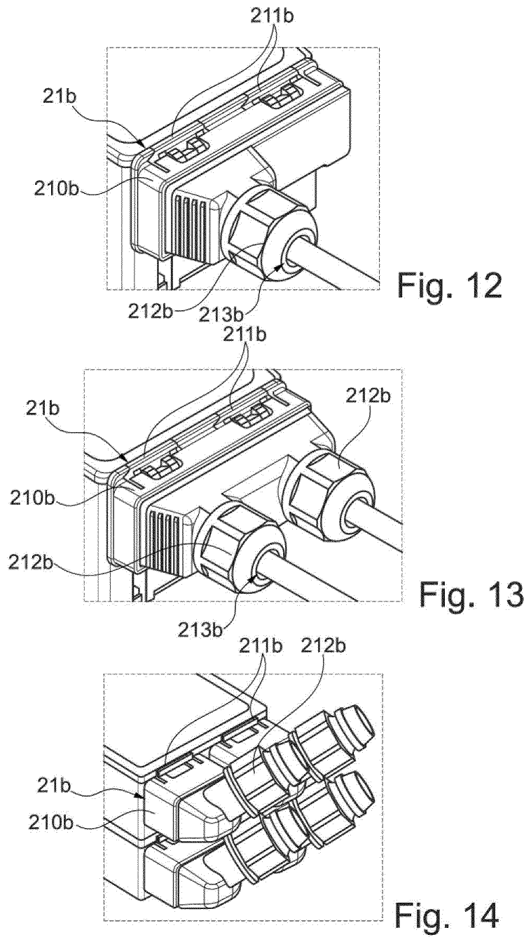

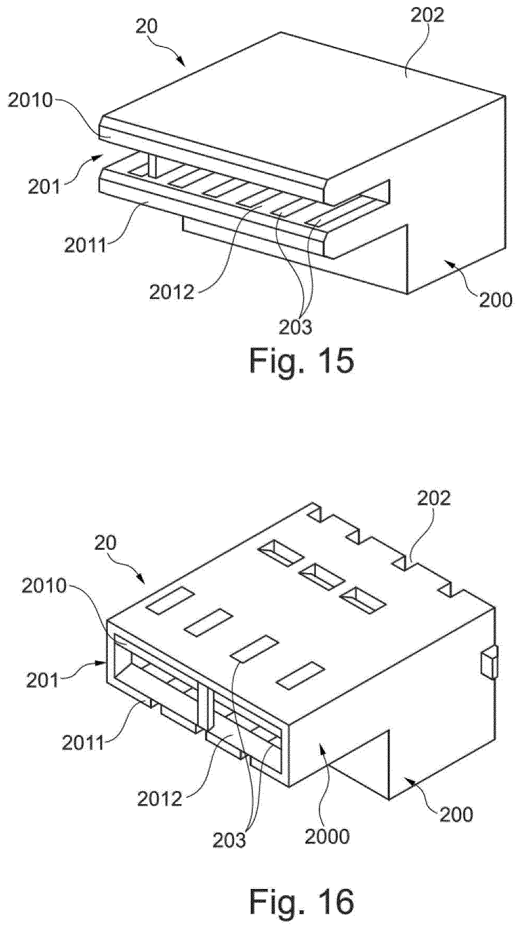

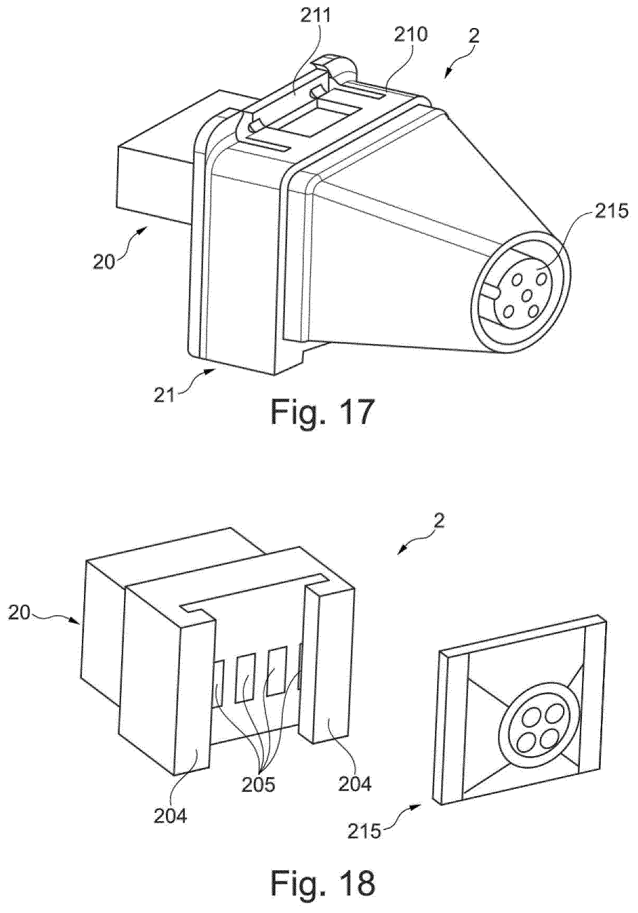

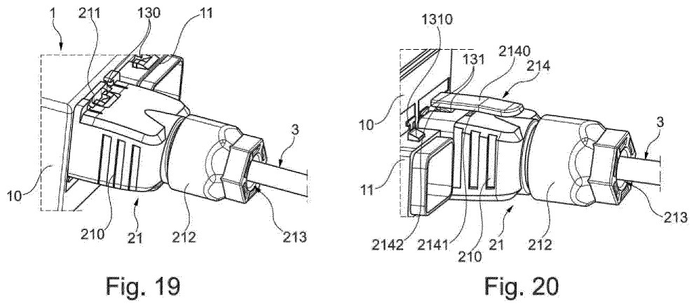

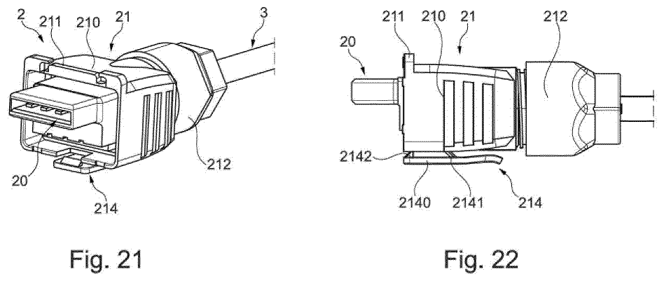

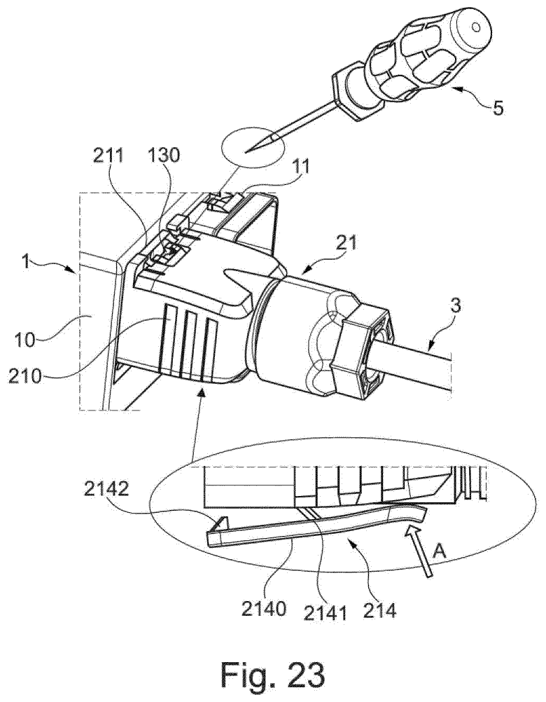

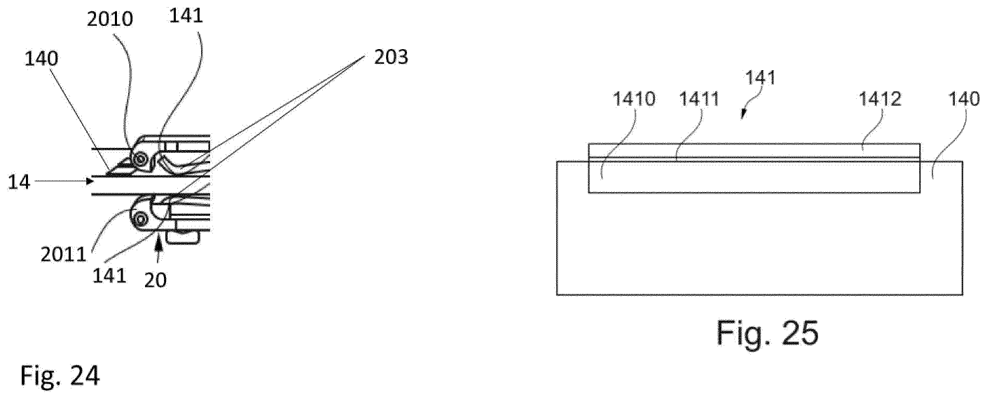

In the back view a sealing 214a can be seen which is positioned in the tension protection module 21a. The sealing 214a ensures the seal with the counterpart. In the edge in the border position (shown in FIGS. 2, 11) the contour provides a clear and safe tightness.

In this particular embodiment the screw fitting or nut 212a has opposite flat areas 2120a for facilitating tightening of the screw or nut 212a with a suitable tool.

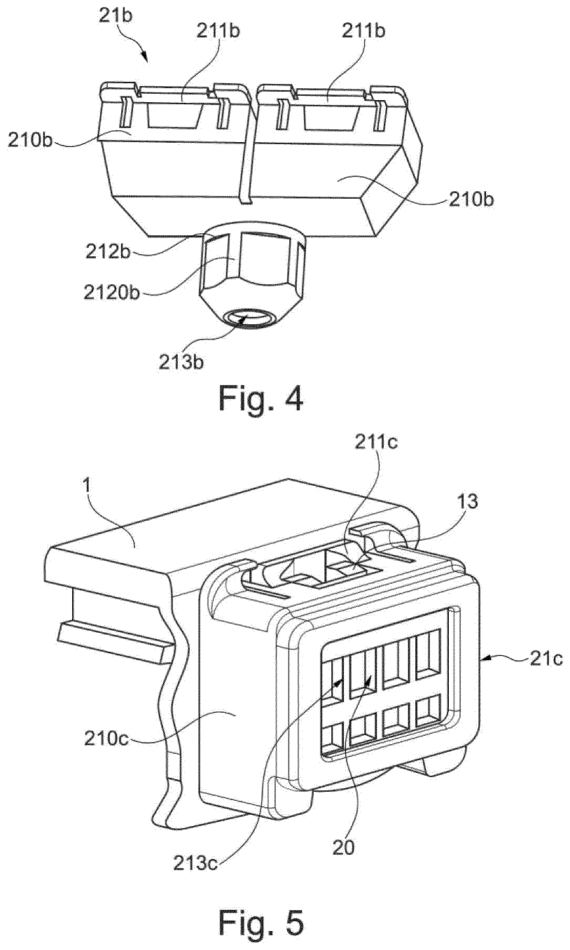

FIG. 4 illustrates a second embodiment of a tension protection module 21b. The tension protection module 21b comprises two socket portions 210b, each of them being suitable for receiving a connecting frame 11 when the module 21b is attached to a housing 1 which has two connecting frames 11 arranged corresponding to the socket portions 210b. Each socket portion 210b has a connecting bracket 211b. The interior space of the socket portions 210b extends into a single connecting piece for connecting a single screw fitting or nut 212b. In this way material and assembly time can be saved and a simpler construction can be provided in case two or more connectors 20 are used in one device.

The other features and functions correspond to the embodiment described above and illustrated in FIG. 3. Instead of two socket portions 210b there may be any number and arrangement of socket portions 210b, depending on the requirements and on the number and arrangement of connectors 20 and respective connecting frames 11 of the housing.

In FIG. 5 a third embodiment of a tension protection module 21c is illustrated. The tension protection module 21c comprises a socket portion 210c and a latching bracket 211c. However, the socket portion 210c does not have a connecting piece. Instead, it has a window (opening) 213c for exposing the back side of the connector 20.

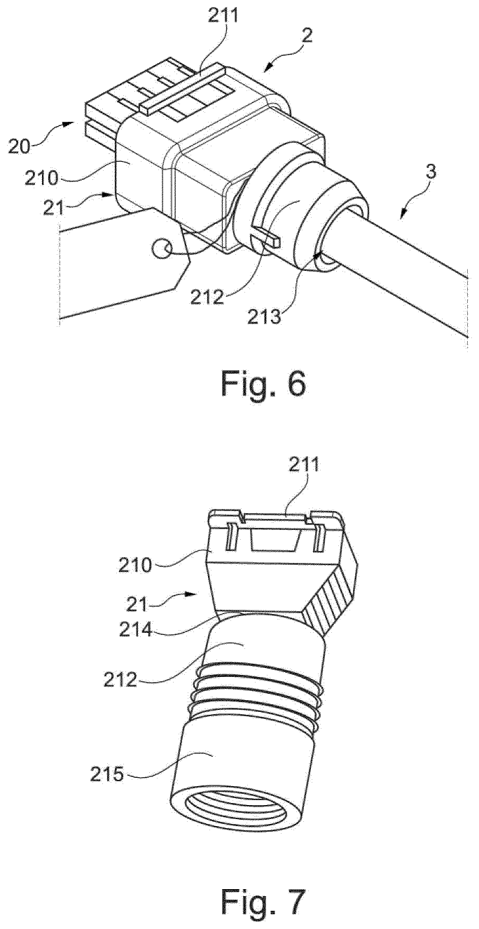

FIG. 6 shows a pre-assembled electrical interface module 2 and cable 3. The ends of the wires of the cable 3 are each connected with a corresponding lead wire of the connector 20. The connector 20 is inserted in the socket portion 210 of the tension protection module 21. The cable 3 is inserted in the opening 213 of the screw fitting 212 and fixed by tightening the screw fitting 212 in a suitable relative position of the cable 3 and the connector 20.

This pre-assembled part 2, 3 can easily be mounted to the housing 1 by inserting at least the front part of the connector 20 into the slot 12 of the housing 1. In a final position the ends of lead wires of the connector 20 directly contact with corresponding connecting terminals of the PCB of the device.

Simultaneously, the socket portion 210 of the tension protection module 21 is shifted over the frame 11 of the housing 1 to finally enclose the frame 11 and establish a latching connection between the latching bracket 211 and the corresponding connecting lug 13 of the connecting frame 11. In this way a secure connection is provided and a defined position of the cable 3 relative to the housing 1 is fixed.

In this embodiment the screw fitting 212 is circular and does not have any flat areas. Therefore, uncontrolled rotation and removal of the screw fitting can be prevented.

FIG. 7 discloses another embodiment of the present disclosure. The socket portion 210 and a connecting part 214 of the tension protection module 21 correspond to the first embodiment described with reference to FIG. 3. However, instead or in addition to a fixing screw fitting or nut 212, a fixing element 215 is provided for fixing a conduit to the tension protection module 21. A conduit enclosing the cable or wires may be needed for high demanding applications.

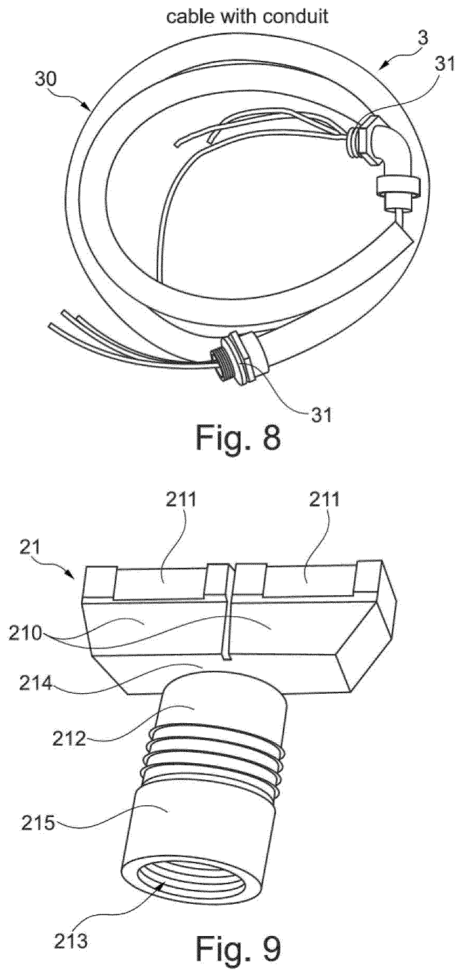

An example for a cable 3 enclosed in a conduit 30 is shown in FIG. 8. The conduit 30 has connecting elements 31 corresponding to the fixing element 215 of the tension protection module 21.

FIG. 9 discloses another embodiment of the present disclosure. The socket portions 210 and the connecting part 214 of the tension protection module 21 correspond to the second embodiment described with reference to FIG. 4. However, instead or in addition to a fixing screw fitting or nut 212, a fixing element 215 is provided for fixing a conduit to the tension protection module 21.

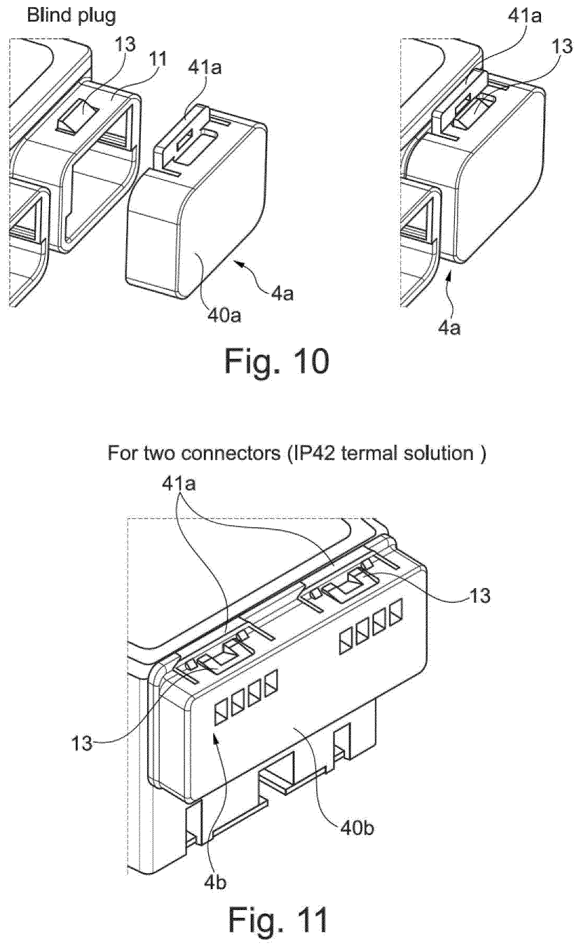

FIG. 10 discloses an embodiment a of blind plugs 4a. The blind plug 4a according to FIG. 10 is for covering one slot 12 defined by a connection frame 11. The blind plug 4a comprises a cover plate 40a and a bracket 41a corresponding to brackets 211a, 211c of the tension protection modules, in order to establish a latching connection with the connection frame 11.

FIG. 11 discloses another embodiment of a tension protection module 4b, e.g. for two IP20 terminal solutions. It corresponds to the solution shown in FIG. 5, but it refers to a device 21 for two connectors. The tension protection module has brackets 211b for establishing a latching connection with the connection latching lugs 13.

FIGS. 12 to 14 show variants of the second embodiment of the present disclosure described with reference to FIG. 4.

The tension protection modules 21b are suitable for covering two/four (FIGS. 12, 13/FIG. 14) slots 13 and connecting two/four cables with two/four corresponding connectors 20. Each of the tension protection modules 21b has at least two socket portions 210b defining one or two inner spaces (they may be separated or not). Each of the tension protection modules 21b has at least two connection brackets 211b for establishing a latching connection with a corresponding connecting lug 13 of the housing 1. Furthermore, each of the tension protection modules 21b has at least one connecting part and at least one screw fitting or nut 212b for fixing one or more wires in a defined position relative to the tension protection module 21b.

In the embodiment according to FIG. 12 two slots are covered, but there is only one cable connection. In the embodiment of FIG. 13 two connectors, and two screw fittings or nuts 212b are provided, e. g. for a low voltage connection (24 V) and a high voltage connection (230 V). In the embodiment of FIG. 14 two connectors, and two screw fittings or nuts 212b are provided.

FIGS. 15 and 16 illustrate embodiments of a solder-free connector.

The solder-free connector according to FIG. 15 corresponds to prior art and discloses a connector 20 having a housing with side walls 200, a front side 201 and a back side 202. The front side or edge includes an upper edge 2010, a lower edge 2011, and a gap 2012 formed in between. In the gap 2012 there are contact ends 203 of lead wires of the connector 20. The gap 2012 is provided for receiving a portion of the PCB for establishing a contact between the contacts 203 and corresponding terminals formed in the portion of the PCB. Contact ends 203 may be provided on the inner side of the upper housing portion (ending in the upper edge 2010) and/or on the inner side of the lower housing portion (ending in the lower edge 2011). Correspondingly, the PCB provided in the housing 1 of the device may have contacts on the top surface and on the bottom surface thereof. This embodiment of a connector may not be used as a high voltage (230 V) plug and play connector (e. g. PVB direct plug), because for plug and play application of the connector at the construction site predetermined distances to the exposed conductive parts must be maintained.

The embodiment according to FIG. 16 differs in that there are side wall portions 2000 of the side walls 200 that extend on both sides over the side opening of the gap 2012. In other words: The housing has been extended in the front portion of the connector 20, and the sides have been closed by additional wall portions 2000. The advantage of this embodiment is that the connector may be used in a high voltage (230 V) plug and play PVB direct plug application.

FIGS. 17 and 18 illustrate an alternative embodiment of an electrical interface module 2 according to the present disclosure.

In the embodiment according to FIG. 17 the tension protection module 21 comprises a socket 215 for a plug. The socket may be adapted to a particular application. The socket 215 may be exchangeable in order to select a socket adapted to the particular application. Especially, the socket 215 may be adapted to country specific standard sockets/plugs.

In the embodiment according to FIG. 18 the connector 20 has a support bracket 204 which is suitable for receiving a socket device 215. When the socket device 215 is inserted in the support bracket 215, rear contacts 205 of the connector 20 contact corresponding terminals of the socket (not shown) and a country specific plug may be plugged in the socket. Like in the embodiment of FIG. 17 the socket device 215 may be adapted to a specific application or country standard.

In both embodiments the adapter or socket device 215 may be part of the connector 20 or of the tension protection module 21 or connected to the connector 20 or of the tension protection module 21 and standard plugs/sockets may be provided for various applications.

In another embodiment according to FIGS. 19 and 20 the same reference numbers are used for the same elements as in the previous embodiments.

The device includes a housing 1 having a housing body 10 consisting of walls that determine an inner space of the housing 1, connecting frames 11 which establish an edge of receiving spaces 12/slots 12 for receiving any connector. At the outer face of the connecting frames 11 connecting protrusions 130, 131 are formed. Protrusions 130, 131 form parts of a connection between the housing 1 and a tension protection module 21. Whereas projection 130 is provided for a positive fit connection, projection 131 is provided for a snap or latch connection. Projections 130 and 131 respectively, are, formed on opposite sides of the connecting frame 11.

Furthermore, the device includes a tension protection module 21 comprising a socket portion 210 which is suitable for receiving a connecting frame 11 when the module 21 is attached to the housing 1.

On a first side (in this example top side; FIG. 19) of the connecting frame 11a connecting bracket 211 is formed at the socket portion 210 for establishing a positive fit connection. When being connected, the bracket engages with the protrusion 130 formed at the frame part 11 of the housing 10 for removably fixing the module 21 to the housing 1. The bracket 211 defines an edge section of a lug which receives the protrusion 130. The lug may only be removed from the protrusion 130 by means of a tool. In the context of the present disclosure a positive fit connection is any connection that is not simply releasable without a tool.

On an opposite side (in this example bottom side; FIG. 20) the socket portion 210 has a snap or latch connection element 214 for removably fixing the module 21 to the housing 1. The snap or latch connecting element 214 comprises a lever portion 2140, a pivot axis 2141 and a snap/latch protrusion 2142 which engages a recess 1310 formed behind the protrusion 131. The snap/latch connecting element 214 may be actuated by a user without using a tool by swivelling the lever 2140 around axis 2141 for disengaging protrusion 2142.

By combining a positive fit connection on one side of the frame 11 and a snap/latch connection on the other side of the frame 11a connection is provided which allows disengagement on the first side only by using a tool, i.e. an unintended disengagement is prevented, and which allows a simple disengagement by hand on the other side, thereby simplifying the process of removing the module 21 from the housing 1.

FIGS. 21 and 22 illustrate an electrical interface module 2 comprising a connector 20 and a tension protection module 21 according to the construction shown in FIGS. 19 and 20.

The construction of the snap or latch connecting element 214 can be seen best in FIG. 22. It comprises a lever portion 2140, a pivot axis 2141 and a snap/latch protrusion 2142. The snap/latch connecting element 214 may be actuated by pressing the side of the lever 2140 opposite the snap/latch protrusion. FIG. 23 schematically illustrates the process of removal of the tension protection module 21 from the housing 1. The positive fit connection 130, 211 is removed using a tool 5, e.g. a screwdriver. The tip of the tool is introduced in a space beneath the bracket 211 and used as a lever for lifting the bracket 211 in order to release the positive fit connection. A slot may be formed in the protrusion 130 in order to facilitate easy insertion of the screwdriver beneath the bracket.

Releasing the snap/latch connection 214, 131 is illustrated schematically in the lower portion of FIG. 23. Actuation on the lever 2140 as indicated by an arrow A makes the lever 2140 swivel around axis 2141, thus releasing the snap/latch protrusion 2142 from protrusion 131.

FIG. 24 illustrates another aspect of the present disclosure, namely, a printed circuit board (PCB) 14 which may be installed in a housing of a field device according to the present disclosure, and a corresponding connector 20 of an electric interface module 2. The PCB 14 has an insulating substrate 140 and conductive contact terminals (connecting terminals) 141. The connector 20 comprises contacts 203 which may be in contact, particularly in solderless contact, with the contact terminals 141 of the PCB 14 when being connected. The contacts 203 are tin-plated. The contacts 203 may have flexible arms to provide a clamp connection with the substrate 140 of the PCB 14.

FIG. 25 shows a sectional view of the PCB 14 through a connector terminal 141 provided on the substrate 140. The connector terminal 141 comprises a copper layer 1410, an ENIG layer 1411 which is a surface finish of the copper contacts 1410 of the printed circuit board 14. On top of the ENIG layer 1411 there is a layer 1412 made of solder paste comprising tin (Sn) which is provided for ensuring non-reactive contact with the tin-plated contacts 203 of the connector 20.

The contact ends 203, as shown in FIG. 24, are provided on the inner side of the upper housing portion (ending in the upper edge 2010) and on the inner side of the lower housing portion (ending in the lower edge 2011) of connector 20. The PCB 14 may have corresponding tin-plated contacts 141 on the top surface and the bottom surface of the substrate 140.

In this way suitable materials may be used for fulfilling different functions of the contacts 203 and contact terminals 141, and the contact materials of the contacts 203 and contact terminals 141 are adapted to each other in order to avoid chemical reactions and oxidation/reduction effects between the contacts 203 and the contact terminals 141.

1. A device for use in an HVAC application, the device comprising:
a housing having walls determining an inner space, wherein the housing has at least one slot configured to receive a connector, and a mounting section;
a printed circuit board (PCB) arranged in the housing, the PCB configured to control and operate the device, wherein the PCB comprises connecting terminals; and
a modular electrical interface, comprising:
at least one connector configured to supply power and/or carry signals to the PCB, the connector having lead wires, wherein the connector is received in the slot of the housing, wherein the lead wires have a solder-free connection to corresponding connecting terminals of the PCB; and
a tension protection module fixed to the mounting section of the housing;
wherein the connector is a direct PCB connector.

2. (canceled)

3. The device according to claim 1, wherein the tension protection module is removably fixed to the mounting section by a latching connection.

4. (canceled)

5. The device of claim 1,
wherein the tension protection module is fixed to the mounting section of the housing by a fixation, wherein the fixation includes at least a first connecting element which comprises a latch connector or a snap connection, and a second connecting element which comprises a positive fit connection.

6-8. (canceled)

9. The device according to claim 1, wherein the mounting section of the housing comprises a frame part, and the tension protection module is fixed to the frame part.

10. (canceled)

11. The device according to claim 1, wherein the tension protection module comprises two or more socket portions fixed to corresponding mounting sections of the housing.

12. The device according to claim 1, wherein the tension protection module comprises a window configured to expose a portion of the connector.

13. The device according to claim 1, wherein the tension protection module comprises a connection part having an opening configured to receive at least one cable, and a fixing element configured to fix the at least one cable in a position relative to the tension protection module.

14. The device according to claim 5, wherein the latch connector or snap connector is configured to engage with a corresponding third connecting element of the mounting section, and the positive fit connector is configured to engage with a corresponding fourth connecting element of the mounting section,

15. (canceled)

16. The device according to claim 14, wherein the latch connector or snap connector comprises a pivotable lever which is actuatable to disengage the latch connector or snap connector from the third connecting element.

17. The device according to claim 14, wherein the positive fit connector comprises a lug having an opening configured to provide a positive fit engagement with the fourth connecting element.

18. The device according to claim 17, wherein the fourth connecting element comprises a protrusion which engages the opening of the lug.

19. The device according to claim 18, wherein the opening of the lug is defined by a bracket portion which may be actuated using a tool configured to disengage the lug from the protrusion.

20. The device according to claim 1, wherein the connector comprises an insulation housing having connection elements configured to connect with corresponding connection elements provided in the slot of the housing configured to fix the connector in the corresponding slot of the housing and/or fix the connector to the tension protection module.

21-23. (canceled)

24. A method of mounting a device according to claim 1, the method comprising:
a. pre-mounting the connector, the tension protection module and a cable to obtain the modular electrical interface and the cable connected thereto;
b. inserting the connector at least partly in the slot of the housing and fixing the modular electrical interface to the housing.

25. A device for use in an HVAC application, the device comprising:
a housing having walls determining an inner space, wherein the housing has at least one slot configured to receive a connector, and a mounting section; and
a printed circuit board (PCB) arranged in the housing and configured to control and operate the device, wherein the PCB comprises connecting terminals;
wherein at least one of the connecting terminals of the PCB has a first layer comprising gold (Au) and a second layer comprising tin (Sn) deposited on the first layer.

26. The device according to claim 25, wherein
the device comprises a modular electrical interface, comprising:
at least one connector configured to supply power and/or carry signals to the PCB, the connector having contacts, wherein the connector is received in the slot of the housing, wherein the contacts have a solder-free connection to the corresponding contact terminals of the PCB.

27. The device according to claim 26, wherein
the connector has at least one contact which is tin (Sn) plated.

28. The device according to claim 25, wherein
the device comprises a tension protection module fixed to the mounting section of the housing.

29-30. (canceled)

31. A method of manufacturing the device according to claim 25, the method comprising:
a. providing a PCB having contacts;
b. depositing a first layer comprising gold (Au) on at least one of the contact;
c. depositing a second layer on the first layer, wherein the second layer comprises tin (Sn).

32-33. (canceled)

34. The method according to claim 31, comprising a further step d) of reflow soldering applied to the second layer deposited on the first layer.
